(19) United States
(12) Patent Application Publication
(10) Pub. No.: US 2024/0415254 A1
(43) Pub. Date: Dec. 19, 2024

(54) KEY STORAGE CASE

(71) Applicants: HARUWA CO., LTD, Sayama City (JP); MKN LLC, Ube-city (JP); NANAKAZE CO., LTD, Ageo-city (JP)

(72) Inventor: Kou NAGAHIRO, Ube-city (JP)

(21) Appl. No.: 18/703,726

(22) PCT Filed: Sep. 30, 2022
(86) PCT No.: PCT/JP2022/036650

§ 371 Date: Apr. 23, 2024

(30) Foreign Application Priority Data
Nov. 2, 2021 (JP) 2021-179798

(51) Int. Cl. A45C 11/32

(52) U.S. Cl. CPC A45C 11/32

(57) ABSTRACT

To provide a mechanism for a smart key storage case for preventing a relay attack, the mechanism allowing the inner space of the smart key storage case to be simply closed by one hand, while achieving the signal-blocking effect of the smart key storage case. According to an embodiment, a smart key storage case includes a housing body including an upper side wall body, a lower side wall body opposed to the upper side wall body, and a side wall body across the upper side wall body and the lower side wall body. The front side wall body includes an opening in communication with an internal space defined by the upper side wall body, the lower side wall body and the side wall body, and an opening/closing body openably/closably closing the opening. At least any one of an inner surface and an outer surface of the housing body is configured by a member that shields at least any one of radio waves transmitted from a key disposed in the internal space and radio waves received by the key. The lower side wall body includes an inclined surface.

### CROSS REFERENCE TO RELATED APPLICATIONS

This application is a National Stage Entry of International Patent Application No. PCT/JP2022/036650, filed on Sep. 30, 2022, which claims priority from and the benefit of Japanese Patent Application No. 2021-179798, filed on Nov. 2, 2021, each of which is hereby incorporated by reference for all purposes as if fully set forth herein.

### BACKGROUND

### Field

The present disclosure relates to a key storage case that prevents relay attacks.

### DISCUSSION OF BACKGROUND

A remote keyless entry system is known as a system for wirelessly controlling unlocking and locking of a vehicle. In the remote keyless entry system, the on-vehicle device periodically transmits a request signal wirelessly, the mobile device of the user who approaches the vehicle returns an answer signal in response to the request signal, and the on-vehicle device responds based on the answer signal, authenticates a key that has the function of receiving radio waves or transmitting radio waves (hereinafter referred to as a “smart key”), and controls unlocking and locking of the vehicle according to the authentication result.

Relay attacks are known as a vehicle theft method for remote keyless entry systems. A relay attack is a method of relaying a request signal from a vehicle to a user's portable device using a repeater so as to cause the smart key to transmit an answer signal and illegally unlock the vehicle.

As a conventional countermeasure against relay attacks, for example, in Patent Document 1, it has been shown that depending on a smart key storage case of a vehicle, it is possible to prevent vehicle theft due to relay attacks by configuring an on-vehicle device or a smart key used in the existing keyless entry system to be able to shield signals transmitted/received between the on-vehicle device and the smart key of the keyless entry system without modifying the on-vehicle device or the smart key of the keyless entry system.

### SUMMARY

However, although the smart key storage case in the background described above is a storage case that can shield request signals and answer signals, is provided with an opening in a portion so that the smart key can be stored from the outside, and has a lid portion for closing the opening, the premise was that the internal space of the storage case would be closed off by the lid portion.

In addition, the smart key storage case based on the above-mentioned background does not assume any adjustment of the key position after the key is stored in the internal space, and has the disadvantage that it becomes difficult to determine the key position within the internal space.

The present application has been made in order to solve the above-mentioned problems, and the purpose thereof is to provide a mechanism that allows the internal space to be easily closed with one hand while having the effect of shielding the signal of the conventional smart key storage case.

In order to solve the above problems, the smart key storage case that prevents relay attacks of the present application includes a housing body having an upper side wall body, a lower side wall body opposed to the upper side wall body, and a side wall body across the upper side wall body and the lower side wall body. The side wall body includes a front side wall body, a rear side wall body opposed to the front side wall body, a first wall body across the front side wall body and the rear side wall body, and a second wall body opposed to the first wall body. The front side wall body includes an opening in communication with an internal space defined by the upper side wall body, the lower side wall body and the side wall body, and an opening/closing body openably/closably closing the opening. At least any one of an inner surface and an outer surface of the housing body is configured by a member that shields at least any one of radio waves transmitted from a key disposed in the internal space and radio waves received by the key. The lower side wall body includes a first inclined surface that is inclined so as to become lower toward at least any one of the front side wall body, the rear side wall body, the first wall body and the second wall body.

As a second feature, the first inclined surface is inclined so as to become lower from the front side wall body toward the rear side wall body.

As a third feature, at least any one of the first wall body and the second wall body includes a second inclined surface that is inclined so as to expand the internal space from the front side wall body toward the rear side wall body.

As a fourth feature, the opening/closing body is configured to be rotatable toward the internal space.

As a fifth feature, at least any one of the front side wall body and the opening/closing body includes a magnet fixing the opening/closing body to the front side wall body.

According to the present application, when storing the smart key in the case, it is possible to easily close the internal space with one hand without having a complicated structure. It also makes it easier to locate the smart key within the internal space.

### BRIEF DESCRIPTION OF THE DRAWINGS

FIG. 1 is diagram showing an overall configuration of a smart key storage case that prevents relay attacks according to an embodiment;

FIG. 2 is a diagram showing a configuration in which an opening/closing portion of the smart key storage case that prevents relay attacks is in an open state;

FIG. 3 is a diagram showing a structure of an internal space of a housing body;

FIG. 4 is a diagram showing a structure of a lower side wall body, which is a portion where the smart key is placed, of the structure of the internal space of the housing body;

FIG. 5 is a diagram showing an overall configuration of a smart key storage case that prevents relay attacks according to a second embodiment; and

FIG. 6 is a diagram showing a structure in which 0 smart key slides down both the lower side wall body and side wall body in the smart key storage case that prevents relay attacks according to the second embodiment.

### DETAILED DESCRIPTION

Hereinafter, each embodiment of the present application will be described with reference to the accompanying drawings. In the description of the following drawings, identical or similar portions are marked with the same or similar signs. However, the drawings are schematic.

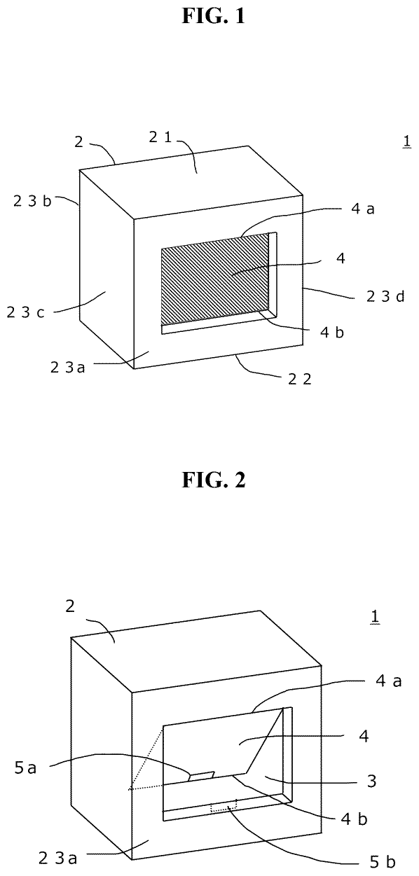

The overall configuration according to the embodiment will be described. FIG. 1 is a diagram showing an overall configuration of a smart key storage case that prevents relay attacks according to an embodiment.

As shown in FIG. 1, the smart key storage case 1 that prevents relay attacks is configured by a housing body 2. The housing body 2 is preferably configured as a cube or a rectangular parallelepiped, but the housing body 2 may have a curved surface at least in part of the outer surface or inner surface of the housing body.

The housing body 2 has an upper side wall body 21, a lower side wall body 22 opposed to the upper side wall body 21, and a side wall body 23 across the upper side wall body 21 and the lower side wall body 22. The side wall body 23 includes a front side wall body 23a, a rear side wall body 23b opposed to the front side wall body 23a, a first wall body 23c across the front side wall body 23a and the rear side wall body 23b, and a second wall body 23d opposed to the first wall body 23c.

The front side wall body 23a includes an opening portion 3 (shown in FIG. 2) in communication with an internal space defined by the upper side wall body 21, the lower side wall body 22 and the side wall body 23, and an opening/closing portion 4 (hatched line portion) openably/closably closing the opening. An upper portion 4a of the opening/closing portion 4 is fixed to the front side wall body 23a, and is movable while being fixed to the front side wall body 23a by a hinge or the like. On the other hand, a lower portion 4b of the opening/closing portion 4 is not fixed to the front side wall body 23a and is rotatable into the internal space of the housing body 2.

FIG. 2 is a diagram showing a configuration in which an opening/closing portion 4 of the smart key storage case that prevents relay attacks is in an open state. As shown in FIG. 2, a magnet 5a is attached to the lower portion 4b of the opening/closing portion 4, and when the opening/closing portion 4 is closed, the magnet 5a and a magnet 5b attached to the front side wall body 23a stick together, thereby the internal space is closed and a sealed state is maintained. Note that, the magnets 5a and 5b may be of any structure such as Velcro (registered trademark) or snap-button, as long as they maintain a sealed state, or only any one of the magnets 5a or 5b may be a magnet, and the other may be a metal. Further, the material for the outside of the housing body 2 is preferably wooden so that the effect of shielding radio waves from the outside can be easily obtained, but any material other than wooden may be used as long as it is an insulating material that shields radio waves.

When holding the smart key in one hand and pushing the opening/closing portion 4 toward the internal space of the housing body 2 by hand, the magnet 5a attached to the lower portion 4b of the opening/closing portion 4 and the magnet 5b attached to the front side wall body 23a are separated to reveal the opening portion 3, and the lower portion 4b of the opening/closing portion 4 moves into the internal space of the housing body 2.

When taking hand out of the internal space of the housing body 2 after storing the smart key in the internal space housing body 2, the lower portion 4b of the opening/closing portion 4 automatically returns to the original position due to its weight. The magnet 5a attached to the lower portion 4b of the opening/closing portion 4 that has returned to the original position and the magnet 5b attached to the front side wall body 23a stick together again, thereby closing the opening portion 3 and sealing the internal space of the housing body, creating a state in which a shielding effect can be exerted.

In this way, the smart key storage case that prevents relay attacks according to the present application has the following effect: the magnet 5a attached to the lower portion 4b of the opening/closing portion 4 and the magnet 5b attached to the front side wall body 23a stick together, so that the smart key can be easily stored in the case with one hand and the internal space of the case can be sealed without troublesome operations such as removing the lid portion, and a high shielding effect can be obtained without adopting a complicated sealing structure.

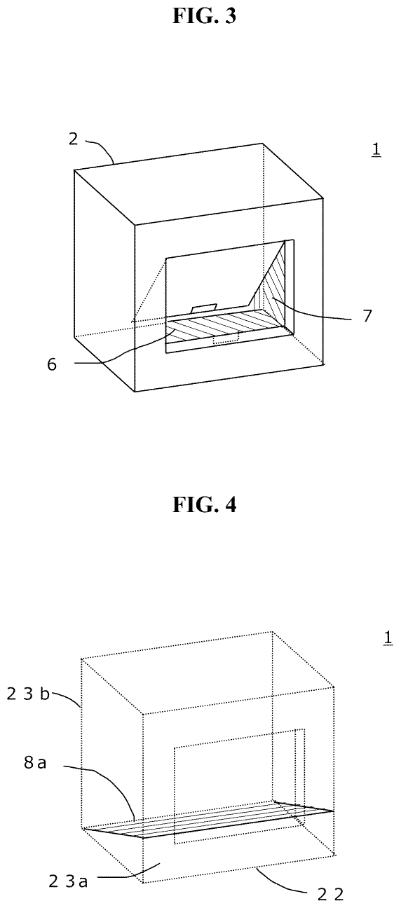

FIG. 3 is a diagram showing a structure of an internal space 6 of a housing body 2. The inner wall of the internal space 6 of the housing body 2 is covered with a radio wave shielding material 7 such as aluminum so that radio waves are shielded. As a result, the internal space 6 of the housing body 2 is shielded from radio waves from the outside, and relay attacks can be prevented by shielding at least any one of the radio waves transmitted from the smart key disposed in the internal space 6 and the radio waves received from the smart key. Note that, the material covering the internal space 6 of the housing body 2 is not limited to the radio wave shielding material 7, but may be any material that shields radio waves. Further, in FIG. 3, the explanation has been made using a configuration in which the internal space 6 of the housing body 2 is covered with the radio wave shielding material 7 as an example, but it is not necessarily limited to the configuration in which the internal space 6 is covered with the radio wave shielding material 7. The outer surface of the housing body 2 may be covered with the radio wave shielding material 7, or the housing body 2 itself may be made of the radio wave shielding material 7.

FIG. 4 is a diagram showing a structure of an inclined portion 8a (first inclined surface) included in the lower side wall body 22 of the housing body 2, which is a portion of the internal space 6 of the housing body 2 where the smart key is placed. The inclined portion 8a is inclined so that it becomes lower from the front side wall body 23a toward the rear side wall body 23b, and when the smart key is inserted from the opening/closing portion 4 and placed on the inclined portion 8a, the smart key slides down and moves from the front side wall body 23a to the rear side wall body 23b.

Since the internal space 6 of the housing body 2 is maintained in a sealed state, the owner of the smart key cannot confirm the internal space 6, but by providing the inclined portion 8a, the smart key always moves to the rear side wall body 23b, thereby fixing the position of the smart key in the internal space 6 of the housing body 2, which has the effect of saving the time and effort of searching for the smart key by hand.

Note that the inclination angle of the inclined portion 8a may be any number of degrees as long as the smart key can slide down and move to the rear side wall body 23b. Further, the inclined portion 8a does not need to be a straight line, but may have an circular-arc shape or the like as long as it has a structure where the smart key can slide down.

The inclination angle of the inclined portion 8a may be any number of degrees, but the angle is preferably such that the smart key placed in the internal space 6 of the housing body 2 is easily taken out. This makes it easier to take out.

The inclined portion 8a has an inclination such that the smart key slides to the rear side wall body 23b, but may also have an inclination such that the smart key slides down to the front side wall body 23a.

### Second Embodiment

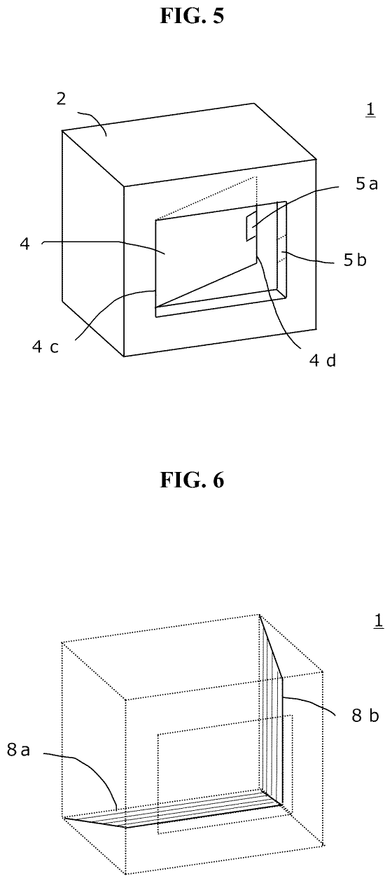

Next, the overall configuration according to the second embodiment will be described. FIG. 5 is diagram showing an overall configuration of a smart key storage case 1 that prevents relay attacks according to a second embodiment.

As shown in FIG. 5, the smart key storage case 1 that prevents relay attacks is configured by a housing body 2 and an opening/closing portion 4. A side portion 4c of the opening/closing portion 4 is fixed to the housing body 2 with a hinge or the like, while a magnet 5a is attached to a side portion 4d opposite to the side portion 4c of the opening/closing portion 3, and is attached so as to be rotatable into the internal space 6. When the opening/closing portion 4 is closed, a magnet 5b provided on the front side wall body 23a and the magnet 5a stick together to maintain a sealed state.

In the case where the magnet 5a is attached to the side portion 4d opposite to the side portion 4c of the opening/closing portion 4, the opening/closing portion 4 does not naturally return from the open state to the closed state by gravity as in the first embodiment, but it is possible for the opening/closing portion 4 to return from the open state to the closed state by attaching a spring or the like to the side portion 4c of the opening/closing portion 4. Note that it is not limited to the spring, and any mechanism that restores the closed state may be used.

If the opening/closing portion 4 has such a configuration, it is also possible to provide the opening/closing portion 4 on the upper side wall body 21 of the housing body 2 instead of the side wall body 23 of the housing body 2.

Although the embodiments of the present application have been described above, the smart key storage case that prevents relay attacks according to the present application is not limited to the above embodiments, and can be implemented with various modifications.

For example, in the first and second embodiments, the opening/closing portion 4 has a structure in which only the lower portion 4b or the side portion 4c can be opened and closed, but it may has a structure in which the lower portion 4b can be opened and closed as shown in FIG. 2 and the side portion 4d can be opened and closed as shown in FIG. 5. Thus, the relay attack prevention smart key storage case can be used either vertically or horizontally, and the case can be fitted depending on the location.

In such a form, an inclined portion 8b (second inclined surface) where the smart key slides down may also be provided on at least any one of the first wall body 23c and the second wall body 23d as shown in FIG. 6. In this way, both the lower side wall body 22 and the side wall body 23 may have a structure where the smart key slides down. Further, in order to make it easier to take out the smart key, the lower side wall body 22 or the side wall body 23 may be configured to become narrower as it goes deeper, so that the smart key can be accommodated in one place.

1. A key storage case comprising a housing body which comprises an upper side wall body, a lower side wall body opposed to the upper side wall body, and a side wall body across the upper side wall body and the lower side wall body, wherein
the side wall body comprises a front side wall body, a rear side wall body opposed to the front side wall body, a first wall body across the front side wall body and the rear side wall body, and a second wall body opposed to the first wall body,
the front side wall body comprises an opening in communication with an internal space defined by the upper side wall body, the lower side wall body and the side wall body, and an opening/closing body openably/closably closing the opening,
at least any one of an inner surface and an outer surface of the housing body is configured by a member that shields at least any one of radio waves transmitted from a key disposed in the internal space and radio waves received by the key,
the lower side wall body comprises a first inclined surface that is inclined so as to become lower toward at least any one of the front side wall body, the rear side wall body, the first wall body and the second wall body.

2. The key storage case of claim 1, wherein
the first inclined surface is inclined so as to become lower from the front side wall body toward the rear side wall body.

3. The key storage case of claim 1, wherein
at least any one of the first wall body and the second wall body comprises a second inclined surface that is inclined so as to expand the internal space from the front side wall body toward the rear side wall body.

4. The key storage case of any one of claim 1, wherein
the opening/closing body is configured to be rotatable toward the internal space.

5. The key storage case of any one of claim 1, wherein
at least any one of the front side wall body and the opening/closing body comprises a magnet fixing the opening/closing body to the front side wall body.
